(19) United States
(12) Patent Application Publication
(10) Pub. No.: US 2008/0061843 A1
(43) Pub. Date: Mar. 13, 2008

(54) Detecting voltage glitches

(76) Inventor: Asier Goikoetxea Yanci, Scotland (GB)

Correspondence Address: FISH & RICHARDSON P.C., PO BOX 1022, MINNEAPOLIS, MN, 55440-1022, US

(21) Appl. No.: 11/519,382

(22) Filed: Sep. 11, 2006

(51) Int. Cl. H03K 5/153

(52) U.S. Cl. 327/78

(57) ABSTRACT

In some implementations, an apparatus includes a filter circuit that receives an input signal and generates in response a filtered signal; and a comparison circuit that receives the input signal and the filtered signal, and outputs in response a comparison output signal having a first level when a magnitude of the filtered signal is less than or substantially equal to a magnitude of the input signal and a second level when the magnitude of the filtered signal is greater than the magnitude of the input signal. The filter circuit can be configured to generate the filtered signal including applying a first transfer function to the input signal when the magnitude of the input signal is substantially constant or increasing, and applying a second transfer function to the input signal when the magnitude of the input signal is decreasing.

### TECHNICAL FIELD

The disclosed implementations relate to electrical circuits.

### BACKGROUND

Secure integrated circuit cards, commonly referred to as smart cards, may be of the form of an embedded integrated circuit hardware device that is small enough to fit into a user's pocket. Secure integrated circuit cards can be used in many situations where critical information must be stored and shared. For example, set-top boxes that facilitate pay-per-view or video-on-demand features can use a secure integrated circuit card to supply user account information to a provider along with a request for access to such features, and to subsequently decrypt encrypted digital video streams that may be provided in response to the request. As another example, a Subscriber Identity Module (SIM) card in a Global Systems for Mobile Communications (GSM) phone can be used to store a user's personal information, such as his or her phone book, device preferences, preferred network(s), saved text or voice messages and service provider information. A SIM card can allow a user, for example, to change handsets while retaining all of his or her information on the SIM card. Smart cards can be used in a variety of applications (e.g., electronic payment systems, including specialized auto-debit devices such as public transportation cards and personal identification documents, such as passports, drivers licenses, and medical identification cards).

Because of the potential value of data stored in a smart card, a conventional smart card employs various techniques to secure the protected data, including physically protecting circuits that store the protected data and encrypting the data and data processing algorithms in various ways. Hackers may employ various techniques to access or corrupt the protected data. For example, a hacker may grind off a portion of the smart card packaging in order to access internal signals and bypass security measures that may be in place. A hacker may slow or speed up a clock signal or subject a power supply to voltage glitches—actions that may have the effect of placing the hardware in a vulnerable state. In particular, a hacker may inject a voltage glitch on a smart card voltage supply or voltage reference rail, for example, to temporarily shift the threshold voltages of transistors or logic gates. In some implementations, such a voltage glitch can cause the hardware to skip certain procedures, allowing the hacker to commandeer portions of the logic, hijack data before it is encrypted, obtain information regarding device architecture or the protected data itself, etc.

### SUMMARY

In some implementations, an apparatus includes a filter circuit that receives an input signal and generates in response a filtered signal; and a comparison circuit that receives the input signal and the filtered signal, and outputs in response a comparison output signal having a first level when a magnitude of the filtered signal is less than or substantially equal to a magnitude of the input signal and a second level when the magnitude of the filtered signal is greater than the magnitude of the input signal. The filter circuit can be configured to generate the filtered signal including applying a first transfer function to the input signal when the magnitude of the input signal is substantially constant or increasing, and applying a second transfer function to the input signal when the magnitude of the input signal is decreasing.

The input signal can be a voltage signal corresponding to a voltage supply rail of a system. The filter circuit and the comparison circuit can be configured to detect a voltage glitch on the voltage supply rail. The filter circuit and the comparison circuit can be configured to detect a voltage glitch on the voltage supply rail that causes, within a predetermined time period, a level of the voltage supply rail to begin at substantially a nominal voltage level, rise to a maximum voltage level, and settle back to substantially the nominal voltage level. In some implementations, the predetermined time period is substantially 10 nanoseconds or less. In some implementations, the predetermined time period is substantially 100 nanoseconds or less.

In some implementations, the filter circuit includes a complementary metal-oxide semiconductor (CMOS) inverter having a voltage supply input, a voltage reference input, a logic input and a logic output; and a diode having an anode terminal and a cathode terminal. In some implementations, the voltage supply input of the CMOS inverter is coupled to the cathode terminal of the diode, the anode terminal of the diode is coupled to the input signal, the voltage reference input of the CMOS inverter is coupled to a ground reference of the system, the logic input of the CMOS inverter is coupled to a voltage level substantially corresponding to the ground reference of the system, and the logic output of the CMOS inverter provides the filtered signal. The first transfer function can correspond to a charging function of parasitic capacitance in the CMOS inverter and current through a portion of the CMOS inverter and the diode when the diode is in a forward-biased state. The second transfer function can correspond to a discharging function of parasitic capacitance in the CMOS inverter and current through a portion of the CMOS inverter and the diode when the diode is in a reverse-biased state.

The comparison circuit can include a comparator having a positive input, a negative input and a comparator output; wherein, the positive terminal is coupled to the input signal, the negative terminal is coupled to the logic output of the CMOS inverter and the comparator output provides the comparison output signal.

The apparatus can further include an alarm circuit that receives the comparison output signal and outputs in response an alarm output signal having a first mode or a second mode, wherein the alarm circuit is configured to initially output the alarm output signal in the first mode and output the alarm signal in the second mode when the comparison output signal transitions to the second level. The alarm circuit can include at least one of a latch; a set-reset flip-flop; or a circuit configured to store a value, receive an input, and provide an output based on the input relative to the stored value. The alarm circuit can be configured to persistently output the alarm signal in the second mode once the comparison output signal transitions to the second level.

The apparatus can further include a reset circuit that is configured to cause the alarm circuit to output the alarm signal in the first mode following a reset condition. The apparatus can further include a protective circuit that is activated in response to the alarm circuit outputting the alarm signal in the second mode. The protective circuit can include a reset circuit that resets at least a portion of another circuit that is coupled to the input signal. The protective circuit can include a power control circuit that powers down at least a portion of another circuit that is coupled to the input signal.

In some implementations, a method includes receiving an input signal; determining if a magnitude of the input signal is increasing or remaining substantially constant, or decreasing; generating a filtered signal including applying a first transfer function to the input signal if the magnitude is increasing or remaining substantially constant, and applying a second, different transfer function to the input signal if the magnitude is decreasing; and comparing the filtered signal and the received input signal and providing an output signal having a first level if a magnitude of the filtered signal is less than or equal to the magnitude of the input signal and a second level if the magnitude of the filtered signal is greater than the magnitude of the input signal.

The method can further include latching the value of the output signal when the output signal transitions from the first level to the second level. Providing an output signal having the second level can include detecting a voltage glitch on the input signal. Detecting a voltage glitch on the input signal can include detecting a voltage glitch that causes, within a predetermined time period, a level of the input signal to begin at substantially a nominal level, rise to a maximum voltage level, and settle back to substantially the nominal voltage level. In some implementations, the predetermined time period is substantially 10 nanoseconds or less. In some implementations, the predetermined time period is substantially 100 nanoseconds or less.

In some implementations, a method includes generating an input signal corresponding to a level of a supply voltage of a device; determining if the level is increasing or remaining substantially constant, or decreasing; generating a filtered signal including applying a first transfer function to the input signal if the level is increasing or remaining substantially constant, and applying a second, different transfer function to the input signal if the level is decreasing; and asserting an alarm signal if a magnitude of the filtered signal exceeds a magnitude of the input signal.

The method can further include activating a protective circuit if the magnitude of the filtered signal exceeds the magnitude of the input signal. Activating the protective circuit can include resetting at least a portion of the device. Activating the protective circuit can include powering down at least a portion of the device. The method can further include comparing the filtered signal and the input signal to determine if the magnitude of the filtered signal exceeds the magnitude of the input signal.

The details of one or more implementations are set forth in the accompanying drawings and the description below. Other features, objects, and advantages will be apparent from the description and drawings, and from the claims.

### DESCRIPTION OF DRAWINGS

FIG. 1 is a block diagram of a system that can detect voltage glitches.

FIG. 2 provides a series of waveforms that depict various signals with reference to FIG. 1.

FIG. 3 is a schematic diagram of an exemplary circuit that can implement the system shown in FIG. 1.

FIGS. 4A-F illustrate various alternative configurations for the circuit that is shown in FIG. 3.

FIG. 5 is a block diagram of an exemplary application in which a voltage glitch detector can be employed.

Like reference symbols in the various drawings indicate like elements.

### DETAILED DESCRIPTION

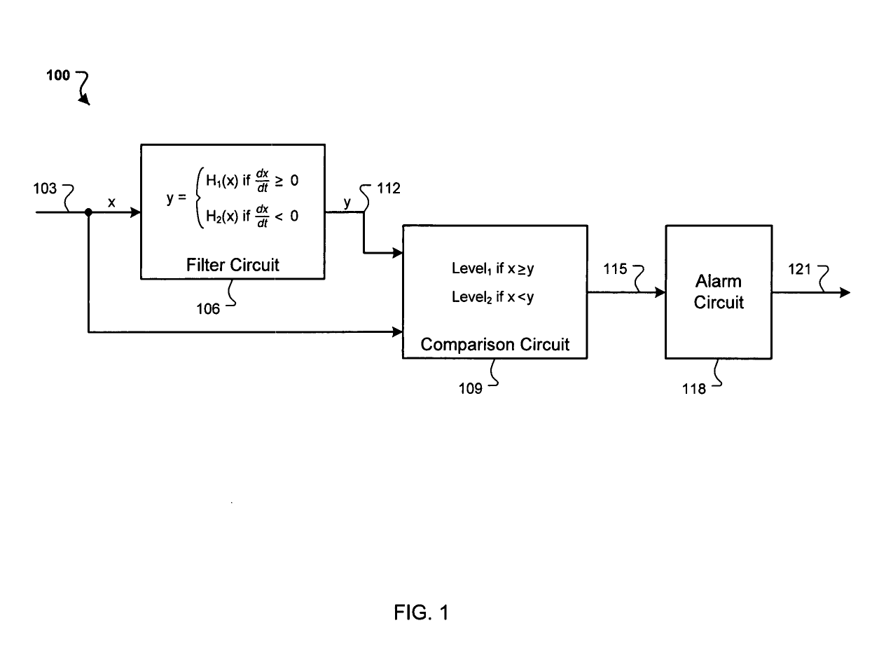

FIG. 1 is a block diagram of a system 100 that can detect voltage glitches on an input signal 103. As shown, in one implementation, the system 100 includes a filter circuit 106 and a comparison circuit 109. The filter circuit 106 receives as input the input signal 103 (e.g., x) and generates in response a filtered signal 112 (e.g., y). In the implementation shown, the filter circuit 106 generates the filtered signal 112 by applying one of two transfer functions to the input signal 103. In particular, if the magnitude of the input signal 103 is substantially constant or increasing (dx/dt is greater than or equal to zero), the filter circuit 106 applies a first transfer function, H₁(x), to the input signal 103. If the magnitude of the input signal 103 is decreasing (dx/dt is less than zero), the filter circuit 106 applies a second transfer function, H₂(x), to the input signal 103.

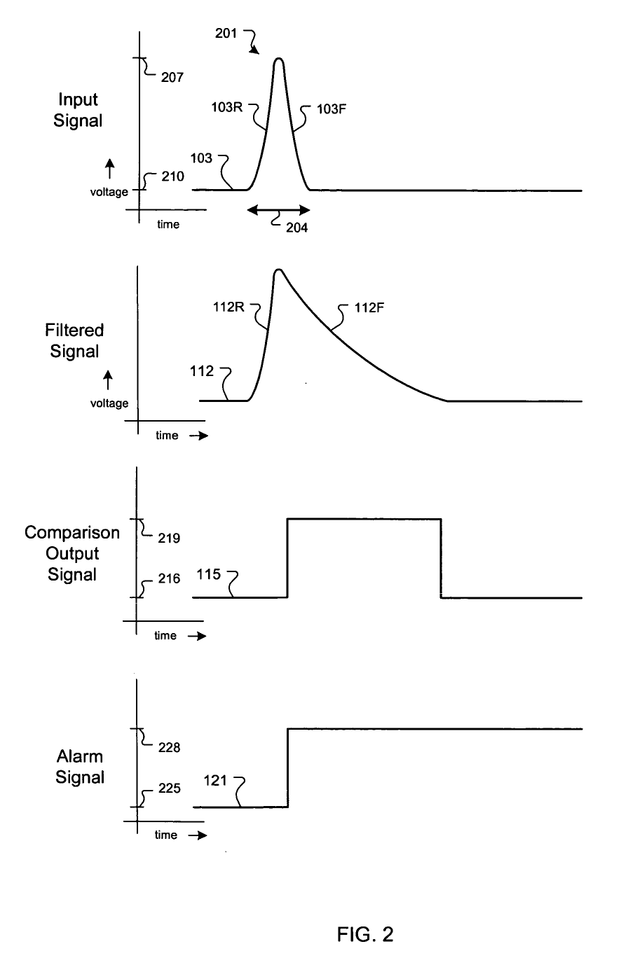

In some implementations, the first transfer function H₁(x) substantially passes the input signal 103 through with little change, and the second transfer function H₂(x) applies a decay function to the input signal 103 that has a small time constant. Thus, the two transfer functions H₁(x) and H₂(x) can have the effect of substantially passing a rising edge of a glitch through while delaying the falling edge of the glitch, as is depicted in FIG. 2 and described in greater detail below.

The time constant associated with the second transfer function H₂(x) can influence the effect the filter circuit 106 has on a glitch on the input signal 103. For example, in some implementations, a very small time constant has very little effect on a long-duration glitch, or a glitch with a very slow falling edge; on the other hand, the same small time constant can have a much greater relative effect on a shorter-duration glitch, or a glitch with a very fast falling edge. Accordingly, the sensitivity of the filter circuit 106 can be tuned by adjusting the time constant corresponding to the second transfer function H₂(x). Put another way, the range of glitch durations and magnitudes that can be detected by the filter circuit 106 can be tuned by adjusting the time constant corresponding to the second transfer function H₂(x).

The comparison circuit 109 receives as input the input signal 103 and the filtered signal 112 and compares their relative magnitudes. Based on the comparison, the comparison circuit 109 outputs a comparison output signal 115 that can have a first level when the magnitude of the filtered signal 112 is less than or substantially equal to the magnitude of the input signal 103, and a second level when the magnitude of the filtered signal 112 is more than the magnitude of the input signal 103.

In operation, the comparison circuit 109 and the filter circuit 106 can detect glitches in the following manner. At steady state (e.g., a state in which the magnitude of the input signal 103 is substantially constant), the filter circuit 106 applies the first transfer function H₁(x) to the input signal 103 to generate a filtered signal 112 having a substantially similar profile as the input signal 103 (e.g., substantially similar shape with a possible small decrease in magnitude). At steady state, because the filtered signal 112 has a substantially similar profile as the input signal 103, the comparison circuit 109 will provide the comparison output signal 115 at the first level.

When the input signal 103 is increasing, as on the rising edge of a positive glitch, the filter circuit 106 will continue applying the first transfer function H₁(x), which, as described above, can pass through the input signal 103 substantially unchanged. Accordingly, when the input signal 103 is increasing, the comparison circuit 109 will again provide the comparison output signal 115 as the first level, since the input signal 103 and the filtered signal 112 have substantially similarly magnitudes.

When the input signal 103 is decreasing, as on a falling edge of a positive glitch, the filter circuit 106 will apply the second transfer function H₂(x) to the input signal 103. As described above, the second transfer function H₂(x) is, in some implementations, a delay function having a time constant. In these implementations, the filter circuit 106 causes the filtered signal 112 to have a delayed and differently shaped response relative to the input signal 103. Accordingly, for glitches in the input signal 103 having sharp falling edges (e.g., fast glitches), the magnitude of the input signal 103 itself will decrease faster than the magnitude of the corresponding filtered signal 112, resulting in a period of time during which the filtered signal 112 will have a greater magnitude than the magnitude of the input signal 103. The comparison circuit 109 detects this condition and provides the comparison output signal 115 during this period at the second level. After some period of time, (e.g., a period of time related to the time constant), the magnitude of the filtered signal 112 will settle back to substantially the same magnitude as the input signal 103, and the comparison circuit 109 will again provide the comparison output signal 115 at the first level.

In some implementations, the comparison circuit 109 requires a minimum amount of time (e.g., a hold time) to detect a difference in magnitudes of the input signal 103 and the filtered signal 112. To meet such a minimum hold time, the time constant can be appropriately tuned (e.g., made sufficiently large) to ensure that a characteristic glitch that the system 100 is designed to detect will cause the filtered signal 112 to have a magnitude that is greater than the magnitude of the input signal 103 for a period of time that is at least as long as the minimum hold time.

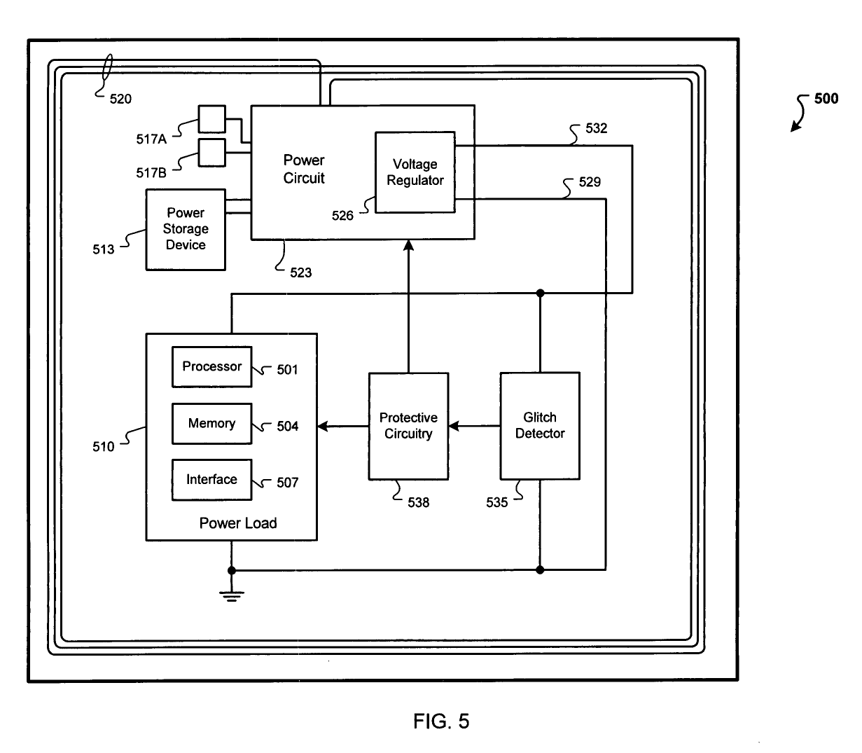

To record the occurrence of a glitch even after the magnitude of the filtered signal 112 has settled back to substantially the same magnitude as the input signal 103, and the comparison circuit 109 has again begun providing the comparison output signal 115 at the first level, the system 100 can include an alarm circuit 118. In some implementations, the alarm circuit 118 latches the value of the comparison output signal 115 when the comparison output signal 115 transitions from the first level to the second level. In this manner, the comparison circuit 109 can provide a signal (e.g., the comparison output signal 115) that indicates that a glitch is occurring, whereas the alarm circuit 118 can provide a signal (e.g., an alarm output signal 121) that indicates that a glitch has occurred. Moreover, the alarm circuit 118 can provide a synchronous indication (e.g., the alarm output signal 121) of a glitch, in place of the asynchronous comparison output signal 115. Other portions of the system 100 (not shown in FIG. 1) can employ the alarm output signal 121 to initiate any action that may be desirable following a glitch, as is described in greater detail with reference to FIG. 5.

FIG. 2 provides a series of waveforms that depict various signals described above with reference to FIG. 1. In particular, FIG. 2 shows a glitch 201 on the input signal 103 having duration 204 and a peak value 207. As shown, the glitch 201 has a rising edge 103R, during which the magnitude of the input signal 103 rises from a nominal value 210 toward the peak value 207, and a falling edge 103F, during which the magnitude of the input signal 103 falls back to the nominal value 210. As shown, the glitch 201 falls smoothly back to the nominal value 210, but in other implementations, the glitch 201 includes a region in which the magnitude of the input signal 103 undershoots the nominal value 210, then increases towards the nominal value 210 (or slightly overshoots the nominal value 210, again undershoots the nominal value 210) and gradually settles out. In these implementations, the duration 204 can include the period starting with the rising edge 103R and ending with the input signal 103 substantially settled out at the nominal value 210.

As shown in one implementation, the filtered signal 112 increases in magnitude in substantially the same manner that the input signal 103 increases. That is, the filtered signal 112 has a rising edge 112R that has substantially the same profile (e.g., slope, timing and relative increase in magnitude) as the input signal 103, when the input signal 103 is increasing. As described above, the rising edge 112R of the filtered signal 112 can result from the filter circuit 106 (shown in FIG. 1) applying the first transfer function H₁(x) to the input signal 103.

As shown in one implementation, the filtered signal 112 deceases in magnitude in a delayed manner relative to a corresponding decrease in magnitude of the input signal 103. That is, the falling edge 112F of the filtered signal 112 is less steep than the corresponding falling edge 103F of the input signal 103. As described above, the falling edge 112F of the filtered signal 112 can result from the filter circuit 106 applying the second transfer function H₂(x) to the input signal 103. In one particular implementation, the profile (e.g., slope of the falling edge 112F at its “midpoint”) can be related to the time constant of the second transfer function H₂(x). That is, the slope of the falling edge 112F at its midpoint can be greater in absolute magnitude when the time constant is smaller, relative to the slope of the falling edge 112F at its midpoint when the time constant is larger.

FIG. 2 also shows the comparison output signal 115. In the implementation shown, the comparison output signal 115 is provided at a second level 219 whenever the magnitude of the input signal 103 is less than the magnitude of the filtered signal 112. Based on the level of the comparison output signal 115, the alarm circuit 118 can initially provide an alarm output signal 121 in a first mode (depicted by the level 225), then provide the alarm output signal 121 in a second mode (depicted by the level 228).

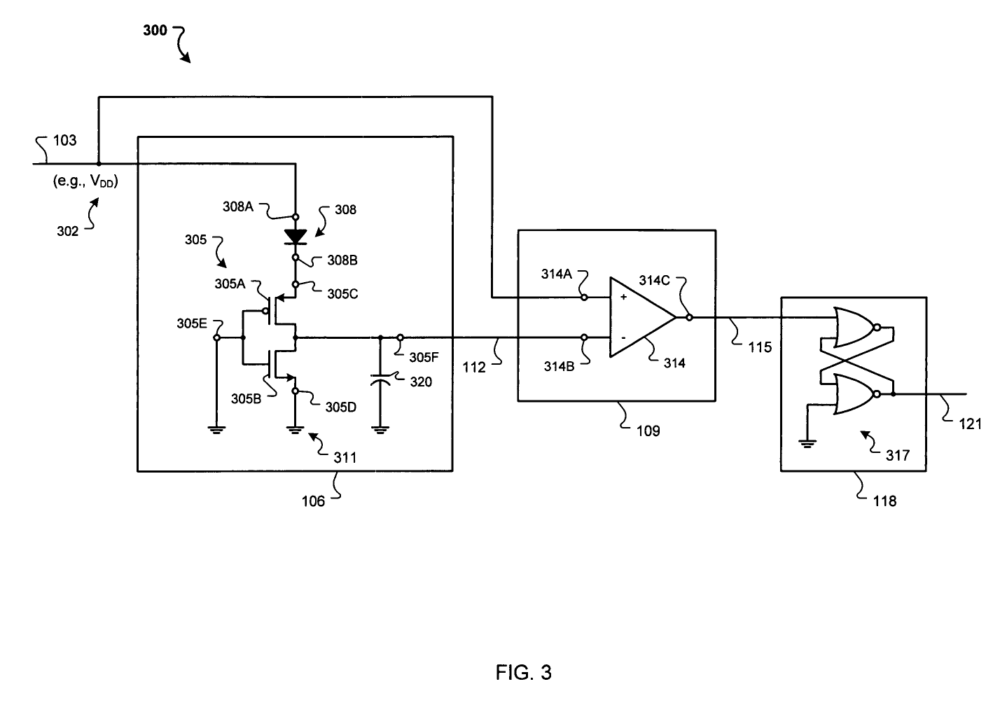

FIG. 3 is a schematic diagram of an exemplary circuit 300 that can implement the system 100 that is shown in FIG. 1. As shown, the input signal 103 can be a voltage signal corresponding to a voltage supply rail 302 of a system. The filter circuit 106, in one implementation, includes a complementary metal-oxide semiconductor (CMOS) inverter 305 having a pMOS (p-channel metal oxide semiconductor (MOS)) transistor 305A, an NMOS (n-channel MOS) transistor 305B, a voltage supply input 305C, a voltage reference input 305D, a logic input 305E and a logic output 305F. The filter circuit 106, as shown, also includes a diode 308 having an anode terminal 308A and a cathode terminal 308B. The anode terminal 308A of the diode 308 is coupled to the input signal 103 (e.g., the voltage supply rail 302 of a corresponding system), the cathode terminal 308B of the diode 308 is coupled to the voltage supply input 305C of the CMOS inverter 305. The voltage reference input 305D of CMOS inverter 305 is coupled to a ground reference 311 of the corresponding system, as is the logic input 305E of CMOS inverter 305. Finally, the logic output 305F of the CMOS inverter 305 provides that filtered signal 112, which is coupled to the comparison circuit 109.

The comparison circuit 109, in one implementation as shown, includes a comparator 314 having a positive input 314A, a negative input 314B, and a comparator output 314C. As shown, the positive input 314A of the comparator 314 is coupled to the input signal 103 (e.g., the voltage supply rail 302), and the negative input 314B of the comparator 314 is coupled to the filtered signal 112, which, as described above, is provided by the logic output 305F of the CMOS inverter 305. The comparator output 314C is coupled to the alarm circuit 118. In one implementation, as shown, the alarm circuit 118 includes a set-reset flip-flop 317. Operation of the exemplary circuit 300 is now described.

The output voltage of the filter circuit 106 (voltage at the logic output 305F and on the filtered signal 112) is described relative to three modes of the input signal 103: the input signal 103 at steady state (e.g., substantially constant); the input signal 103 increasing in magnitude; and the input signal 103 decreasing in magnitude. When the input signal 103 is at steady state, the voltage of the filtered signal 112 is also at steady state and at a magnitude that is slightly lower than the magnitude of the input signal 103. In particular, as shown, the CMOS inverter 305 is configured to provide at its logic output 305F the filtered signal 112 at a value that corresponds to a logic ‘1’ (which is generally characterized by a level that is close to the supply voltage), since its logic input 305E is tied to the ground reference 311 of the system. Because of the diode 308, the maximum steady-state voltage of the logic output 305F of the CMOS inverter 305 will be approximately the voltage of the input signal 103, less a standard voltage drop across the diode 308 when the diode is forward-biased, less any (small) voltage drop across the channel of the pMOS transistor 305A.

When the voltage of input signal 103 is increasing, as on the rising edge of a voltage glitch, the voltage of the logic output 305F also increases. At a fixed current, the rate of increase of the voltage of the logic output 305F is limited by parasitic capacitance of the CMOS inverter 305 (depicted as capacitor 320). However, an increased current is available to charge the parasitic capacitance 320, and counteracts this limit to the increase in voltage. In particular, when the input signal 103 increases, the forward bias across the diode 308 also increases slightly, allowing more current to flow through the diode 308. Moreover, as the voltage of the input signal 103 increases, the gate-source voltage of the pMOS transistor 305A also increases (in absolute magnitude), allowing more current to also flow through the pMOS transistor 305A and charge the parasitic capacitance 320. Because the charge rate of capacitance is related to the current that flows through the capacitance, the increased current, in some implementations, charges the parasitic capacitance 320 very quickly, resulting in a voltage at the logic output 305F (and, correspondingly, on the filtered signal 112) having a profile that is substantially similarly to the voltage profile on the input signal 103 (e.g., with a slightly smaller magnitude, due to the voltage drop(s) described above). Put another way, the CMOS inverter 305 and the diode 308 can pass through increases in voltage on the input signal 103 with little change. Put yet another way, the behavior of the filtered signal 112 (e.g., y) can be described as a first transfer function (e.g., H₁(x)) applied to the input signal 103 (e.g., x) when the magnitude of the input signal 103 is substantially constant or increasing, and the first transfer function can be described as approximately a unity, or near-unity pass-through function.

When the voltage of the input signal 103 is decreasing, as on the falling edge of a voltage glitch, the voltage of the logic output 305F also decreases. In particular, a decreasing voltage on the input signal 103 reduces the forward bias across the diode 308 and reduces the gate-source voltage of the pMOS transistor 305A, both of which reduce the current available to maintain the voltage on the parasitic capacitance 320. As less current is available to maintain the voltage on the parasitic capacitance 320, the voltage will decrease as charge on the parasitic capacitance leaks out or is dissipated by other current paths that are not shown in FIG. 3; however, the rate of decrease in voltage will be limited by the parasitic capacitance 320 (e.g., the voltage will decrease based on a time constant associated with the parasitic capacitance 320). Accordingly, the parasitic capacitance 320 will discharge slower than it is charged. In implementations in which the input signal 103 decreases in magnitude very quickly (e.g., a short-duration glitch, or glitch with a steep falling edge), the voltage of the input signal 103 can dip below the voltage of the filtered signal 112, as the parasitic capacitance is discharging. The duration of time during which such a condition can exist will depend on the time constant associated with the parasitic capacitance 320 and to the slope of the falling edge of the glitch (e.g., the “sharpness” of the glitch). That is, for fast glitches, the CMOS inverter 305 and the diode 308 can pass through decreases in voltage on the input signal 103 in a delayed manner. Put another way, the behavior of the filtered signal 112 (e.g., y) can be described as a second transfer function (e.g., H₂(x)) applied to the input signal 103 (e.g., x) when the magnitude of the input signal 103 is rapidly decreasing relative to a time constant corresponding to the second transfer function, and the second transfer function can be described as a delay function.

As described above, when the input signal 103 is at a steady state or increasing, in magnitude, the filtered signal 112 will have a profile that is similar to the input signal 103, but the magnitude of the filtered signal 112 will be slightly less than the magnitude of the input signal 103. Accordingly, when the magnitude of the input signal 103 is at a steady state or increasing, the comparison circuit 109 will provide the comparison output 115 at a first level. In particular, in one implementation as shown, the comparator 314 will provide the comparison output signal 115 at a first level (e.g., a logic ‘0’), indicating that the level of the positive input 314A is greater than the level of the negative terminal 314B. However, as described above in some implementations, when the input signal 103 is decreasing in magnitude, a condition can exist in which the voltage of the input signal 103 can dip below the voltage of the filtered signal 112, at which point, the comparator 314 will provide the output comparison signal 115 at a second level (e.g., a logic ‘1’), indicating that the level of the positive input 314A is less than the level of the negative input 314B.

As shown in one implementation, the alarm circuit 118 (e.g., a set-reset (SR) flip-flop 317) can capture the transition of the comparison output signal 115 from the first state to the second state and can accordingly switch from a first mode (e.g., a logic ‘0’ on the alarm signal 121, indicating a non-alarm condition) to a second mode (e.g., a logic ‘1’ on the alarm signal 121, indicating an alarm condition). The alarm signal can be provided to other circuits to initiate an appropriate action, examples of which are provided with reference to FIG. 5.

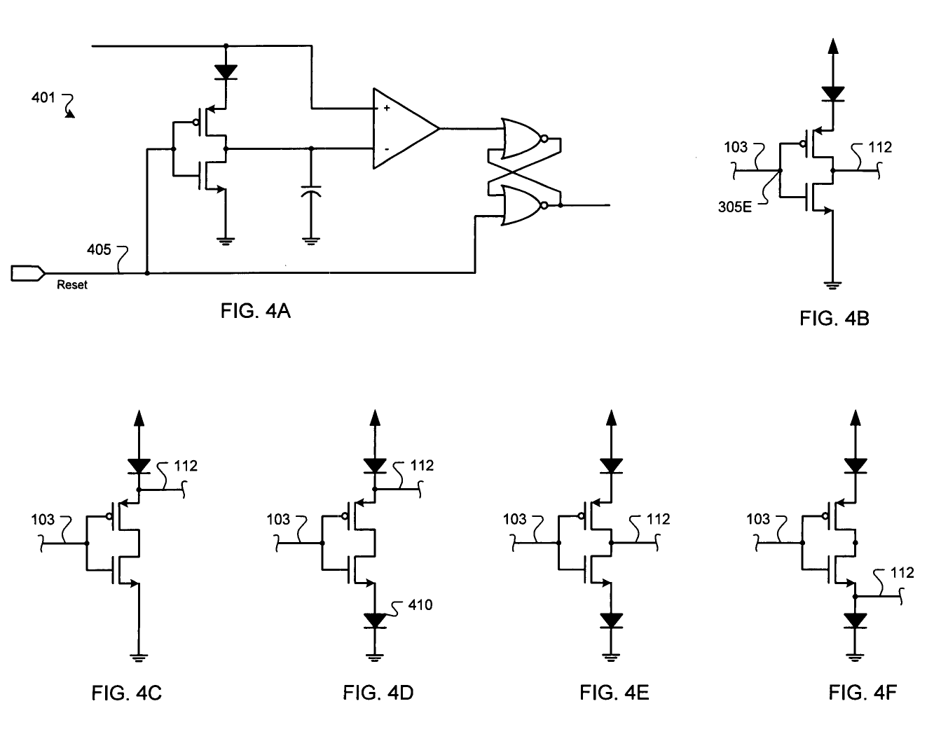

FIG. 3 illustrates one example circuit 300 that can detect positive glitches on an input signal, such as the positive voltage rail of a power supply. Various other circuits are contemplated. For example, FIG. 4A illustrates a circuit 401 that includes a reset line 405 by which the alarm portion of the circuit can be reset. As other examples, FIGS. 4B-4F illustrate various alternative configurations for the filter circuit 106 portion of the circuit 300. In particular, FIG. 4B illustrates a circuit in which the input signal 103 can be applied to the logic input of the CMOS inverter; FIG. 4C illustrates a variation of the circuit shown in FIG. 4B, in which the filtered signal 112 is provided at the cathode terminal/CMOS inverter voltage supply junction, rather than at the logic output of the CMOS inverter. FIGS. 4D-F illustrate variations in which a second diode 410 is added between the CMOS voltage reference input and the voltage reference itself, and the filtered signal 112 is provided by various different terminals of the CMOS inverter. In FIG. 3 and FIGS. 4A-4F, the diodes are shown using a standard diode symbol (e.g., a P-N junction), but any of the diodes shown can also be implemented by an appropriately configured transistor (e.g., with the source connected as the diode anode, and the gate and drain connected to form the cathode).

As the reader will appreciate, the variations shown in FIGS. 4A-4F can be combined with variations in the configuration of the comparison circuit 109 (shown in FIG. 3) in order to detect either positive or negative glitches on either a voltage supply rail or a voltage reference rail. Glitches can also be detected on negative voltage supply rails. In addition, multiple different circuits can be combined to detect multiple kinds of glitches (e.g., positive glitches on a voltage supply rail, negative glitches on a voltage supply rail, positive glitches on a voltage reference rail, negative glitches on a voltage reference rail, etc.). Moreover, multiple circuits configured to detect the same kind of glitch can be provided, each with different time constants, to detect glitches of varying durations or glitches that have rising or falling edges with varying slopes. In particular, each circuit generally detects glitches that have durations and magnitudes that fall within some range (e.g., an operating range, or detection range). The detection range is, in some implementations, related to the time constant of the circuit. Thus, to detect glitches that span a larger range than the detection range of a single circuit, multiple circuits, each with a different time constant, can be combined to expand the overall detection range. As an example of data points within the detection range of an exemplary circuit, applicants simulated a glitch detection circuit in parallel with a load having a nominal supply voltage of 1.6 V; the supply voltage was provided by a voltage regulator that received as input external power at approximately 2.7-3 volts. The simulated glitch detection circuit detected both a first glitch on the external power source of the voltage regulator having a peak voltage of 7 V and a duration of about 100 nanoseconds (ns) (e.g., a glitch in which the external voltage increased from 2.7 V to 7 V, then settled back to 2.7 V, within about 100 ns), and a second glitch on the external power source of the voltage regulator having a peak voltage of 15 V and a duration of 10 ns (e.g., a glitch in which the external voltage increased from about 3 V to 15 V, then settled back to 3 V, within about 10 ns). An example circuit having a voltage regulator, a voltage supply, and an input for providing external power is shown in FIG. 5.

FIG. 5 is a block diagram of an exemplary smart card 500—a device in which voltage detection systems and methods described herein can be employed. The smart card 500 includes a processor 501 that can execute programming instructions stored in memory 504 in order to process data that is also stored in the memory 504 or received through an interface 507. The memory 504 can represent multiple different kinds of memory, such as, for example, ROM or RAM, flash, DRAM, SRAM, etc. For example, in some implementations, program instructions are stored on ROM, and the processor 501 uses some form of RAM to store intermediate data as the programming instructions are executed. The interface 507 can work in conjunction with a wireless communication channel (not shown) that includes, for example, RF (radio frequency) signals that are adapted for a particular communication protocol (e.g., a protocol characterized by ISO/IEC 14443 or ISO/IEC 15693 (ISO refers to the International Organization for Standardization; IEC refers to the International Electrotechnical Commission)). In some implementations, the interface 507 works in conjunction with a wired communication channel (not shown) that is adapted for a particular communication protocol (e.g., a protocol characterized by ISO/IEC 7816 or ISO/IEC 7810).

Together, the processor 501, memory 504 and interface 507, along with other components (not shown), make up a power load 510 that is supplied with power by a power system that is now described. In one implementation, as shown, the smart card 500 can receive power from one of three sources: an internal power storage device 513 (e.g., a battery or power storage capacitor), a direct external power source (e.g., through external power contacts 517A and 517B), or an indirect external power source (e.g., through energy transmitted by radio frequency or other electromagnetic radiation external to the smart card and received by the smart card through a power coil 520). In some implementations, a smart card 500 only employs one of above-described power sources; in other implementations, a smart card employs multiple methods of receiving power (e.g., a combination card).

Once power is received or otherwise provided to the smart card 500, it can be processed by a power circuit 523. In some implementations, the power circuit 523 stores a portion of the received power in a local power storage device (e.g., the power storage device 513, if present). The power circuit 523 can also switch between multiple sources of power. For example, in a “combination card,” the power circuit 523 can switch between a direct external power source (e.g., the power contacts 517A and 517B) and an indirect external power source (e.g., the power coil 520), depending, for example, on whether the smart card 500 is situated in a contact-based card reader that provides power to the power contacts 517A-B or whether the smart card 500 is situated in an electromagnetic field that induces current in the power coil 520.

In one implementation, as shown, the power circuit 523 includes a voltage regulator 526 that provides a voltage reference 529 and a voltage supply 532 to the power load 510. In some implementations, the voltage regulator 526 regulates the voltage supply 532 to a level that is suitable for the power load 510. As shown, the power circuit 523 provides a single voltage supply 532 and voltage reference 529, but in other implementations, additional voltage supplies and/or references can also be provided.

A glitch detector 535 is also included in the smart card 500. In some implementations, the glitch detector 535 includes circuits or performs methods that are described herein. For example, the glitch detector 535 can detect voltage glitches on the voltage supply 532 or voltage reference 529 rails of the smart card 500. The smart card 500 can also include protective circuitry 538 that initiates various actions if the glitch detector 535 detects a voltage glitch. For example, in some implementations, the protective circuitry 538 resets a portion of the smart card 500 (e.g., the processor 501 and/or memory 504) upon detection of a voltage glitch. In some implementations, the protective circuitry 538 powers down at least a portion of the smart card 500 upon detection of a voltage glitch.

In some implementations, a smart card, such as the smart card 500 described herein, is more secure than a smart card that does not include a glitch detector. In particular, the smart card 500 can detect a voltage glitch attack and initiate appropriate action, such as resetting or powering down the smart card 500, to prevent a hacker from obtaining protected information from the smart card 500 through the voltage glitch attack.

A number of implementations have been described. Nevertheless, it will be understood that various modifications may be made without departing from the spirit and scope of the disclosed implementations. For example, smart cards are one application for the circuits and methods described herein, but these circuits and methods can be applied to other devices. Modifications can be made to detect various kinds of glitches, including positive and negative glitches on positive, reference and negative voltage rails. Time constants can be adjusted to detect glitches of varying durations or glitches having rising or falling edges with various slopes. Accordingly, other implementations are within the scope of the following claims.

What is claimed is:

1. An apparatus comprising:
a filter circuit that receives an input signal and generates in response a filtered signal; and
a comparison circuit that receives the input signal and the filtered signal, and outputs in response a comparison output signal having a first level when a magnitude of the filtered signal is less than or substantially equal to a magnitude of the input signal and a second level when the magnitude of the filtered signal is greater than the magnitude of the input signal;
wherein the filter circuit is configured to generate the filtered signal including applying a first transfer function to the input signal when the magnitude of the input signal is substantially constant or increasing, and applying a second transfer function to the input signal when the magnitude of the input signal is decreasing.

2. The apparatus of claim 1, wherein the input signal is a voltage signal corresponding to a voltage supply rail of a system.

3. The apparatus of claim 2, wherein the filter circuit and the comparison circuit are configured to detect a voltage glitch on the voltage supply rail.

4. The apparatus of claim 3, wherein the filter circuit and the comparison circuit are configured to detect a voltage glitch on the voltage supply rail that causes, within a predetermined time period, a level of the voltage supply rail to begin at substantially a nominal voltage level, rise to a maximum voltage level, and settle back to substantially the nominal voltage level.

5. The apparatus of claim 4, wherein the predetermined time period is substantially 10 nanoseconds or less.

6. The apparatus of claim 4, wherein the predetermined time period is substantially 100 nanoseconds or less.

7. The apparatus of claim 1, wherein the filter circuit comprises:
a complementary metal-oxide semiconductor (CMOS) inverter having a voltage supply input, a voltage reference input, a logic input and a logic output; and
a diode having an anode terminal and a cathode terminal;
wherein the voltage supply input of the CMOS inverter is coupled to the cathode terminal of the diode, the anode terminal of the diode is coupled to the input signal, the voltage reference input of the CMOS inverter is coupled to a ground reference of the system, the logic input of the CMOS inverter is coupled to a voltage level substantially corresponding to the ground reference of the system, and the logic output of the CMOS inverter provides the filtered signal.

8. The apparatus of claim 7, wherein the first transfer function corresponds to a charging function of parasitic capacitance in the CMOS inverter and current through a portion of the CMOS inverter and the diode when the diode is in a forward-biased state.

9. The apparatus of claim 7, wherein the second transfer function corresponds to a discharging function of parasitic capacitance in the CMOS inverter and current through a portion of the CMOS inverter and the diode when the diode is in a reverse-biased state.

10. The apparatus of claim 7, wherein the comparison circuit comprises a comparator having a positive input, a negative input and a comparator output; wherein, the positive terminal is coupled to the input signal, the negative terminal is coupled to the logic output of the CMOS inverter and the comparator output provides the comparison output signal.

11. The apparatus of claim 1, further comprising an alarm circuit that receives the comparison output signal and outputs in response an alarm output signal having a first mode or a second mode, wherein the alarm circuit is configured to initially output the alarm output signal in the first mode and output the alarm signal in the second mode when the comparison output signal transitions to the second level.

12. The apparatus of claim 11, wherein the alarm circuit comprises at least one of a latch; a set-reset flip-flop; or a circuit configured to store a value, receive an input, and provide an output based on the input relative to the stored value.

13. The apparatus of claim 11, wherein the alarm circuit is configured to persistently output the alarm signal in the second mode once the comparison output signal transitions to the second level.

14. The apparatus of claim 11, further comprising a reset circuit that is configured to cause the alarm circuit to output the alarm signal in the first mode following a reset condition.

15. The apparatus of claim 1, further comprising a protective circuit that is activated in response to the alarm circuit outputting the alarm signal in the second mode.

16. The apparatus of claim 15, wherein the protective circuit comprises a reset circuit that resets at least a portion of another circuit that is coupled to the input signal.

17. The apparatus of claim 15, wherein the protective circuit comprises a power control circuit that powers down at least a portion of another circuit that is coupled to the input signal.

18. A method comprising:
receiving an input signal;
determining if a magnitude of the input signal is increasing or remaining substantially constant, or decreasing;
generating a filtered signal including applying a first transfer function to the input signal if the magnitude is increasing or remaining substantially constant, and applying a second, different transfer function to the input signal if the magnitude is decreasing; and
comparing the filtered signal and the received input signal and providing an output signal having a first level if a magnitude of the filtered signal is less than or equal to the magnitude of the input signal and a second level if the magnitude of the filtered signal is greater than the magnitude of the input signal.

19. The method of claim 18, further comprising latching the value of the output signal when the output signal transitions from the first level to the second level.

20. The method of claim 18, wherein providing an output signal having the second level comprises detecting a voltage glitch on the input signal.

21. The method of claim 20, wherein detecting a voltage glitch on the input signal comprises detecting a voltage glitch that causes, within a predetermined time period, a level of the input signal to begin at substantially a nominal level, rise to a maximum voltage level, and settle back to substantially the nominal voltage level.

22. The method of claim 21, wherein the predetermined time period is substantially 10 nanoseconds or less.

23. The method of claim 21, wherein the predetermined time period is substantially 100 nanoseconds or less.

24. A method comprising:
generating an input signal corresponding to a level of a supply voltage of a device;
determining if the level is increasing or remaining substantially constant, or decreasing;
generating a filtered signal including applying a first transfer function to the input signal if the level is increasing or remaining substantially constant, and applying a second, different transfer function to the input signal if the level is decreasing; and
asserting an alarm signal if a magnitude of the filtered signal exceeds a magnitude of the input signal.

25. The method of claim 24, further comprising activating a protective circuit if the magnitude of the filtered signal exceeds the magnitude of the input signal.

26. The method of claim 25, wherein activating the protective circuit comprises resetting at least a portion of the device.

27. The method of claim 25, wherein activating the protective circuit comprises powering down at least a portion of the device.

28. The method of claim 24, further comprising comparing the filtered signal and the input signal to determine if the magnitude of the filtered signal exceeds the magnitude of the input signal.
